(19) United States
(12) Patent Application Publication
(10) Pub. No.: US 2008/0073730 A1
(43) Pub. Date: Mar. 27, 2008

(54) Semiconductor device and method for formimg the same

(76) Inventors: Deok-Hyung Lee, Seoul (KR); Sun-Ghil Lee, Yongin-si (KR); Jong-Ryeol Yoo, Osan-si (KR); Byeong-Chan Lee, Yongin-si (KR); In-Soo Jung, Hwasung-si (KR)

Correspondence Address: LEE & MORSE, P.C., 3141 FAIRVIEW PARK DRIVE, SUITE 500, FALLS CHURCH, VA, 22042, US

(21) Appl. No.: 11/902,404

(22) Filed: Sep. 21, 2007

(30) Foreign Application Priority Data
Sep. 22, 2006 (KR) 10-2006-92481

(51) Int. Cl. H01L 29/78; H01L 21/336

(52) U.S. Cl. 257/401; 438/284; 257/E29.128

(57) ABSTRACT

A method for forming a semiconductor device includes forming at least one gate electrode having a bent structure along a first direction on a semiconductor substrate, the gate electrode having first and second vertical portions, forming at least one semiconductor fin along a second direction on the semiconductor substrate, the semiconductor fin positioned between the first and second vertical portions of the gate electrode, forming a first epitaxial layer on the semiconductor fin, the first epitaxial layer including a source/drain impurity region, and forming a second epitaxial layer on the first epitaxial layer, the second epitaxial layer including a contact impurity region.

### BACKGROUND OF THE INVENTION

1. Field of the Invention

Embodiments of the present invention relate to a semiconductor device. More particularly, embodiments of the present invention relate to a semiconductor device with a semiconductor fin and a method for forming the same.

2. Description of the Related Art

Generally, semiconductor devices, e.g., field effect transistors (FETs), may be used as switching devices. However, as integration of the conventional semiconductor device increases, a channel length thereof may decrease and cause a short channel effect, e.g., punchthrough, drain induced barrier lowering (DIBL), subthreshold swing, an increased parasitic capacitance between a junction area and a substrate (junction capacitance), and an increased leakage current. In other words, the reduced channel length of the semiconductor device may degrade operation characteristics thereof, e.g., reduce speed, lower power dissipation, and minimize economy.

As an alternative, a semiconductor device may be formed to have a channel extending vertically with respect to a substrate, as opposed to a planar structure. More specifically, a semiconductor device with a vertical channel, e.g., a FinFET, may include a vertical channel in a semiconductor fin, so that the channel may be surrounded by the gate electrode. As such, the semiconductor device with the vertical channel may be employed in a memory device, e.g., a DRAM cell transistor, thereby decreasing the overall size thereof, securing a threshold voltage suitable for a DRAM refresh characteristic, and minimizing off-state leakage current.

The conventional FinFET may have full depletion (FD) characteristics, thereby including a p-type polysilicon gate, as opposed to a n-type polysilicon gate, in order to increase its threshold voltage. However, use of the p-type polysilicon gate in the conventional FinFET may increase a voltage difference between the p-type polysilicon gate and a source/drain region of the FinFET, thereby enhancing gate induced drain leakage (GIDL). A high GIDL may degrade retention properties of the FinFET and deteriorate reliability and operability of a DRAM employing the FinFET.

### SUMMARY OF THE INVENTION

The present invention is therefore directed to a semiconductor device and a method of forming the same, which substantially overcome one or more of the problems due to the limitations and disadvantages of the related art.

It is therefore a feature of an embodiment of the present invention to provide a semiconductor device with a semiconductor fin and having a reduced gate induced drain leakage.

It is another feature of an embodiment of the present invention to provide a method for forming a semiconductor device with a semiconductor fin and having a reduced gate induced drain leakage.

At least one of the above and other features of the present invention may be realized by providing a semiconductor device, including at least one gate electrode having a bent structure along a first direction on a semiconductor substrate, the gate electrode including first and second vertical portions, at least one semiconductor fin along a second direction on the semiconductor substrate, the semiconductor fin positioned between the first and second vertical portions of the gate electrode, a first epitaxial layer on the semiconductor fin, the first epitaxial layer including a source/drain impurity region, and a second epitaxial layer on the first epitaxial layer, the second epitaxial layer including a contact impurity region.

The gate electrode may include a cell gate electrode in a cell region of the semiconductor substrate and a peripheral circuit gate electrode in a peripheral circuit region of the semiconductor substrate. The gate electrode may enclose portions of three surfaces of the semiconductor fin to form a channel region. The gate electrode may be a p-type polysilicon gate electrode. The gate electrode may be between two portions of the first epitaxial layer. The semiconductor device may further include a spacer between the gate electrode and each of the first and second epitaxial layers. The semiconductor device may further include a mask pattern between the gate electrode and an upper surface of the semiconductor fin.

The second epitaxial layer may be wider than the first epitaxial layer. The second epitaxial layer may be thicker than the first epitaxial layer. The second epitaxial layer may be only in a cell region of the semiconductor substrate. The second epitaxial layer may have a higher average concentration of impurity ions than the first epitaxial layer.

At least one of the above and other features of the present invention may be further realized by providing a method for forming a semiconductor device, including forming at least one gate electrode having a bent structure along a first direction on a semiconductor substrate, the gate electrode having first and second vertical portions, forming at least one semiconductor fin along a second direction on the semiconductor substrate, the semiconductor fin positioned between the first and second vertical portions of the gate electrode, forming a first epitaxial layer on the semiconductor fin, the first epitaxial layer including a source/drain impurity region, and forming a second epitaxial layer on the first epitaxial layer, the second epitaxial layer including a contact impurity region. Forming the gate electrode may include forming spacers along lateral surfaces of the gate electrode.

Forming the first and second epitaxial layers may include implanting impurity ions therein. Implanting the impurity ions may include forming a decreasing concentration of impurity ions as a vertical distance from an upper surface of the semiconductor fin decreases. Forming the second epitaxial layer may include an in-situ impurity ions implantation.

Forming the second epitaxial layer may include forming an insulation layer on the first epitaxial layer, forming an opening in the insulation layer to expose an upper surface of the first epitaxial layer, and performing an epitaxial process on the upper surface of the first epitaxial layer. Forming the second epitaxial layer may include performing the epitaxial process only in a cell region of the semiconductor substrate. Forming the second epitaxial layer may include forming the opening to be wider than the first epitaxial layer. Forming the second epitaxial layer may include performing a hydrogen annealing process to planarize an upper surface of the second epitaxial layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a plan view of a semiconductor device according to an embodiment of the present invention;

FIGS. 2A-2C illustrate cross-sectional views along lines I-I′, II-II′, and III-III′ of FIG. 1;

FIGS. 3A-3C illustrate cross-sectional views of a semiconductor device according to another embodiment of the present invention, the cross-sectional views corresponding to lines I-I′, II-II′, and III-III′ of FIG. 1;

FIGS. 4-12 illustrate cross-sectional views along lines I-I′, II-II′, and III-III′ of FIG. 1 of sequential stages in a method for forming the semiconductor device of FIGS. 2A-2C; and

FIGS. 13-19 illustrate cross-sectional view of sequential stages in a method for forming the semiconductor device of FIGS. 3A-3C, the cross-sectional views corresponding to lines I-I′, II-II′, and III-III′ of FIG. 1.

### DETAILED DESCRIPTION OF THE INVENTION

Korean Patent Application 10-2006-92481 filed on Sep. 22, 2006, in the Korean Intellectual Property Office, and entitled: “Semiconductor Device and Method for Forming the Same,” is incorporated by reference herein in its entirety.

Embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer or an element is referred to as being “under” another layer or element, it can be directly under, or one or more intervening layers or elements may also be present. In addition, it will also be understood that when a layer or an element is referred to as being “between” two layers or elements, it can be the only layer or element between the two layers or elements, or one or more intervening layers or elements may also be present. Like reference numerals refer to like elements throughout.

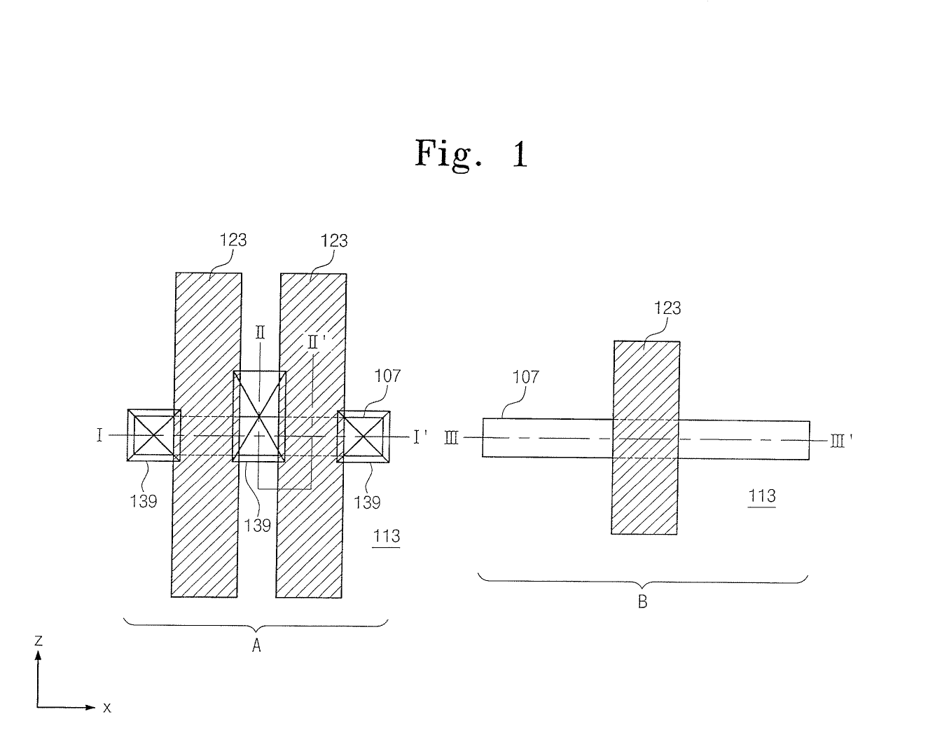

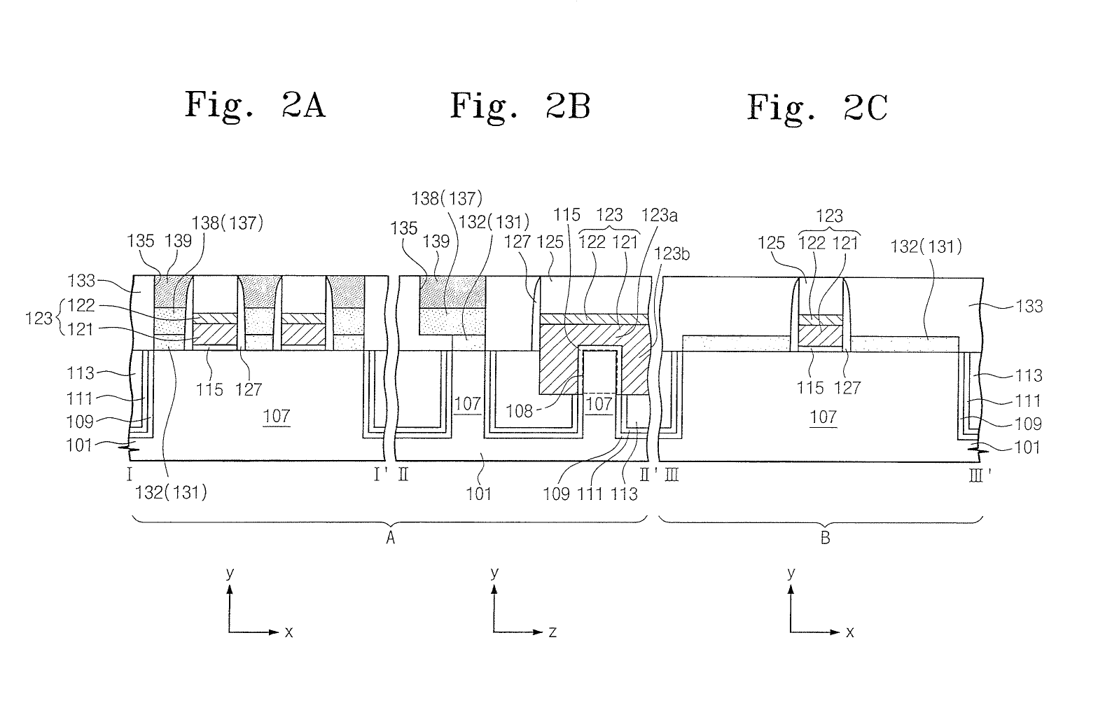

An exemplary embodiment of a semiconductor device according to the present invention will now be more fully described with reference to FIGS. 1 and 2A-2C. FIG. 1 illustrates plan views of a cell region A and a peripheral circuit region B, respectively, of a semiconductor device according to embodiments of the present invention. FIGS. 2A-2C illustrate cross-sectional views of lines I-I′, II-II′, and III-III′ in FIG. 1, respectively. More specifically, FIG. 2A illustrates a cross-sectional view of a semiconductor fin along the x-axis in the cell region A, FIG. 2B illustrates partial cross sectional views of a gate electrode and a region between two adjacent gate electrodes along the z-axis, and FIG. 2C illustrates a cross-sectional view of a semiconductor fin along the x-axis in the peripheral circuit region B.

As illustrated in FIGS. 1 and 2A-2C, a semiconductor device may include at least one semiconductor fin 107 on a semiconductor substrate 101, at least one gate electrode 123 crossing the semiconductor fin 107 on the semiconductor substrate 101, and source/drain regions 132 on the semiconductor fin 107.

More specifically, the at least one semiconductor fin 107 of the semiconductor device may extend along a first direction, e.g., along the x-axis, and may project vertically, i.e., along the y-axis, with respect to the semiconductor substrate 101. Accordingly, the semiconductor fin 107 may include sidewalls projecting vertically away from semiconductor substrate 101, so that a first oxide layer 109 and a nitride liner 111, as illustrated in FIGS. 2A-2C, may be sequentially disposed on the sidewalls of the semiconductor fin 107. When the semiconductor device includes a plurality of semiconductor fins 107, the plurality of semiconductor fins 107 may be spaced apart, so that a device isolation layer 113 may be disposed on the substrate 101 therebetween.

As further illustrated in FIGS. 1 and 2A-2C, the at least one gate electrode 123 of the semiconductor device may extend along a second direction, e.g., along the z-axis, on the substrate 101, so that the gate electrode 123 and the semiconductor fin 107 may cross one another. The gate electrode 123 may be above the semiconductor fin 107, so a gate insulator 115 may be interposed between the semiconductor fin 107 and the gate electrode 123. The first and second directions may be perpendicular.

More specifically, as illustrated in FIG. 2B, the gate electrode 123 may have a bent structure, i.e., a structure having a horizontal portion 123a between two vertical portions 123b, thereby forming, e.g., a cross-sectional area of π (pi). A width of the semiconductor fin 107 along the z-axis may be substantially equal to or less than a distance between the two vertical portions 123b of the gate electrode 123 along the z-axis, so that the semiconductor fin 107 may fit between the vertical portions 123b of the gate electrode 123. In other words, the vertical portions 123b of the gate electrode 123 may extend in a downward direction along the y-axis, i.e., toward an upper surface of the substrate 101, in parallel to the semiconductor fin 107, so the bent structure of the gate electrode 123 may enclose three surfaces of the semiconductor fin 107. Accordingly, an upper surface and lateral surfaces of the semiconductor fin 107 may face the horizontal portion 123a and the vertical portions 123b, respectively, of the gate electrode 123. An upper portion of the semiconductor fin 107, i.e., a portion adjacent to the vertical portions 123b of the gate electrode 123, may be defined as a channel region 108. Both lateral surfaces and an upper surface of the channel region 108 may be used for charge movement.

The gate electrode 123 may include a first conductive pattern 121, e.g., a polysilicon conductive pattern having p-type impurities, and a second conductive pattern 122, e.g., a metal material and/or a silicide. The second conductive pattern 122 may be formed on the first conductive pattern 121, and may be substantially thinner than the first conductive pattern 121, as measured along the y-axis. A hard mask pattern 125 may be formed on the second conductive pattern 122, and a sidewall spacer 127 may be disposed on the substrate 101 along each outer lateral surface of the gate electrode 123, i.e., to cover the hard mask 125 and the first and second conductive patterns 121 and 122, as illustrated in FIG. 2B. When the semiconductor device includes a plurality of gate electrodes 123, the plurality of gate electrodes 123 may be spaced apart, and an interlayer dielectric layer 133 and/or the source/drain region 132 may be disposed on the substrate 101 between adjacent gate electrodes 123.

The source/drain regions 132 of the semiconductor device may be formed on the semiconductor fin 107 between adjacent gate electrodes 123. More specifically, the source/drain regions 132 may be formed in a first epitaxial layer 131 on the semiconductor fin 107, i.e., a layer grown epitaxially from an upper surface of the semiconductor fin 107 and adjacent to each lateral surface of the gate electrode 123, by implanting impurity ions therein. For example, the source/drain regions 132 may be formed in the first epitaxial layer 131 between adjacent gate electrodes 123, as illustrated in FIG. 2A. In this respect, it is noted that the first epitaxial layer 131 may be a non-continuous layer, i.e., a layer having a plurality of discrete segments, on the semiconductor fin 107, so that each segment of the epitaxial layer 131 may be positioned between twp spacers 127 of adjacent gate electrodes 123.

The semiconductor device may further include a second epitaxial layer 137 on the first epitaxial layer 131 in the cell region A. The second epitaxial layer 137 may have a larger width, i.e., as measured along the z-axis, and a larger thickness, i.e., as measured along the y-axis, than the first epitaxial layer 131. A contact impurity region 138 may be formed in the second epitaxial layer 137 by implanting impurity ions therein.

A concentration of impurity ions in the source/drain regions 132 and contact impurity region 138 may decrease with respect to a decreasing vertical distance from the semiconductor fin 107, i.e., the impurity ion concentration may be higher in an upper surface of the contact impurity region 138 than in a lower surface of the source/drain regions 132. For example, the concentration of the impurity ions may be from about 10¹⁷ ions/cm³ to about 10²⁰ ions/cm³.

The semiconductor device may further include a contact pad 139, e.g., a doped polysilicon layer, on each of the contact impurity regions 138, as illustrated in FIGS. 1 and 2A-2C.

Formation of the source/drain impurity regions 132 in the first epitaxial layer 131, as opposed to directly on the semiconductor fin 107, according to an embodiment of the present invention may be advantageous in providing an impurity region separated from a gate electrode 123, i.e., not laid over the gate electrode 123, thereby minimizing gate induced drain leakage (GIDL). When GIDL is minimized in a p-type polysilicon gate electrode, a high threshold voltage may be maintained therein, so that the semiconductor device may exhibit an improved reliability without increasing a width of a gate electrode spacer. Further, the decreased concentration of impurity ions through the contact impurity region 138 and the source/drain regions 132 may reduce an effect thereon of an electric field formed by the gate electrode 123.

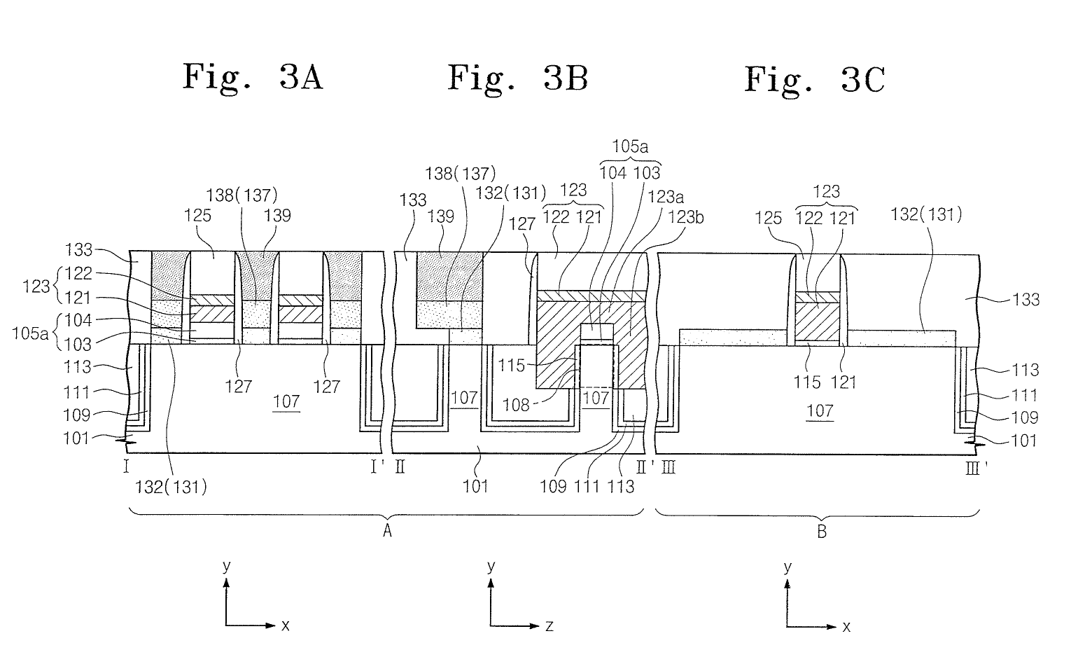

According to another embodiment illustrated in FIGS. 3A-3C, a semiconductor device may be similar to the semiconductor device described previously with respect to FIGS. 1 and 2A-2C with the exception of including a mask pattern 105a on the channel region 108. More specifically, the mask pattern 105a may include an oxide pattern 103a and a nitride pattern 104a, and may be deposited on the channel region 108. As such, the mask pattern 105a may be positioned between an upper surface of the channel region 108 and a lower surface of the horizontal portion 123a of the gate electrode 123, so that charges may not move therethrough. Accordingly, in the embodiment illustrated in FIGS. 3A-3C, only lateral surfaces of the channel region 108 may be used for charge movement.

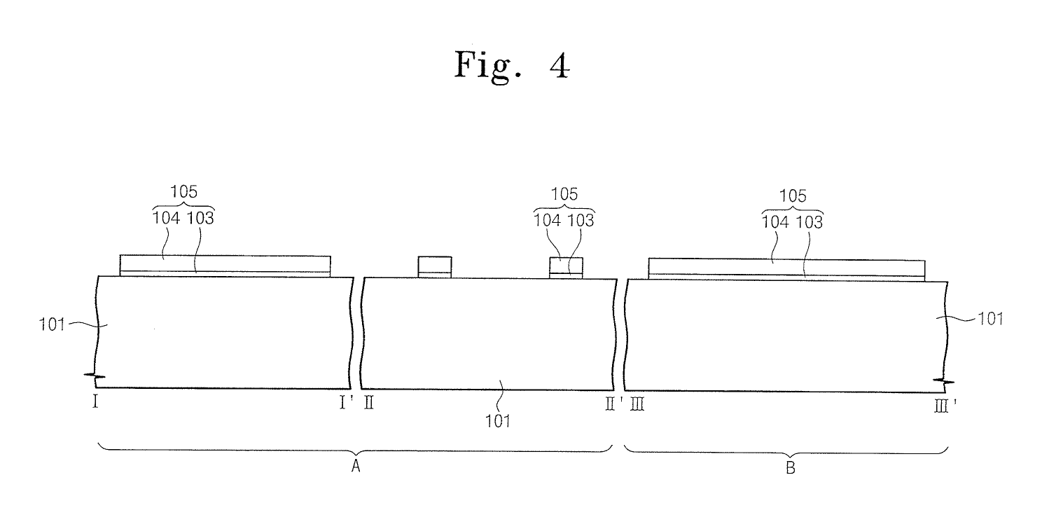

According to yet another embodiment of the present invention, a method for forming the semiconductor device illustrated in FIGS. 1 and 2A-2C will be described in more detail below with respect to FIGS. 4-12. Each of FIGS. 4-12 illustrates three cross-sectional views corresponding to FIGS. 2A-2C, respectively.

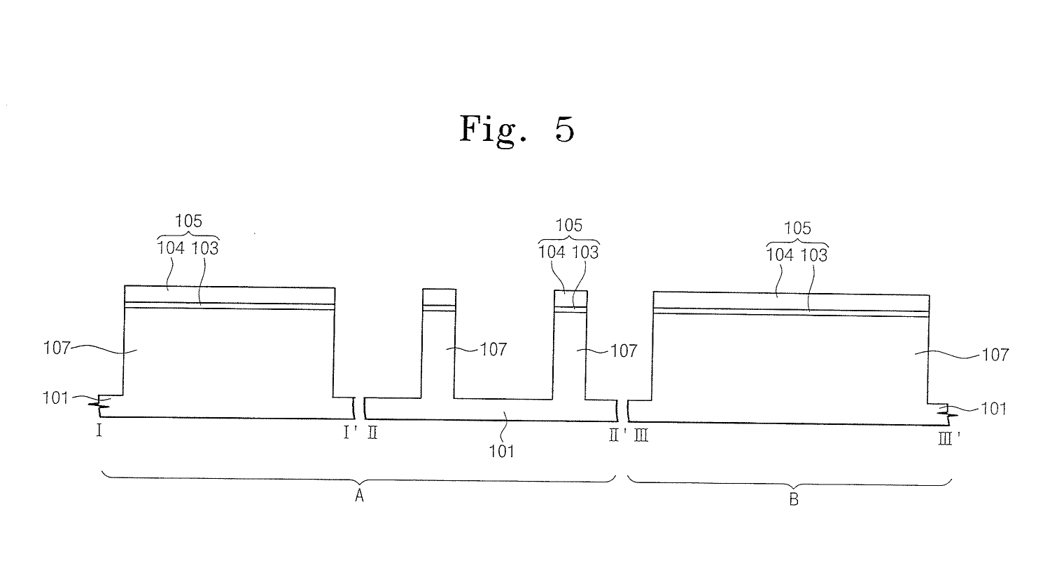

As illustrated in FIG. 4, a mask layer 105 may be formed on the cell and peripheral circuit regions A and B of the semiconductor substrate 101. The mask layer 105 may include a second oxide layer 103 and a nitride layer 104. Using the mask layer 105 as an etch mask, the semiconductor substrate 101 may be etched to form at least one semiconductor fin 107, as illustrated in FIG. 5. Accordingly, the semiconductor fin 107 may be integral with the substrate 101. The semiconductor fin 107 may protrude vertically in an upward direction, i.e., away from the upper surface of the substrate 101.

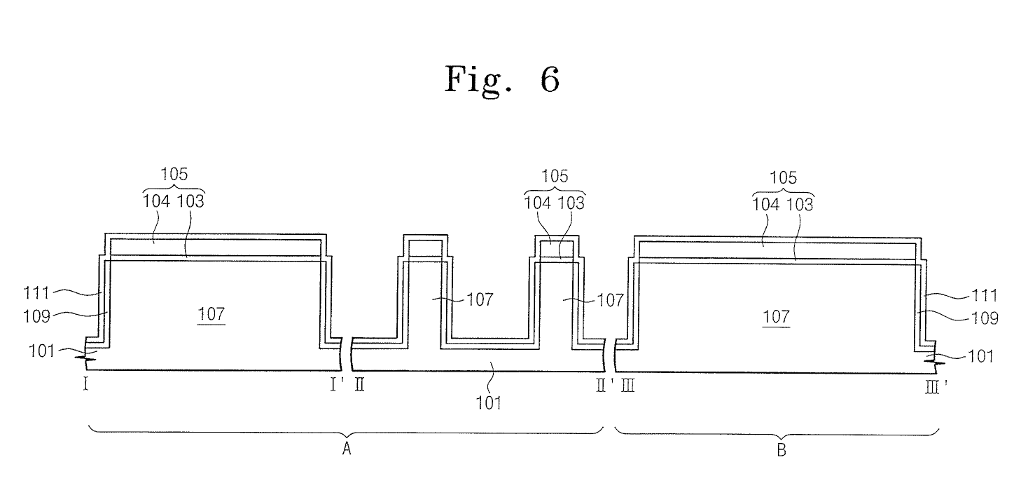

Next, as illustrated in FIG. 6, the first oxide layer 109 may be formed to coat the semiconductor fin 107 and expose portions of an upper surface of the semiconductor substrate 101, followed by deposition of the nitride liner 111 on lateral surfaces of the semiconductor fin 107. The mask layer 105 may remain between the upper surface of the semiconductor fin 107 and the nitride liner 111, e.g., the nitride layer 104 of the mask layer 105 may be in contact with the first oxide layer 109. Formation of the first oxide layer 109 may be performed by, e.g., a thermal oxidation process, to repair potential damage caused to surfaces of the semiconductor fin 107 and the substrate 101 during the etch process, and to reduce stress potentially generated between the nitride liner 111 and the semiconductor fin 107. Formation of the nitride liner 111 may be performed by, e.g., a chemical vapor deposition (CVD) process, to minimize and/or prevent oxidation of the semiconductor fin 107.

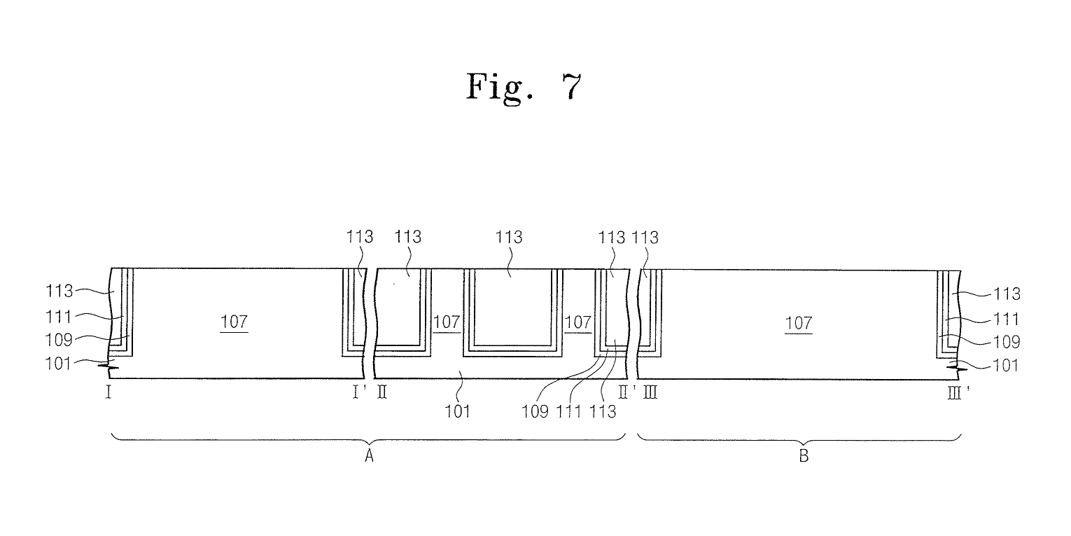

Subsequently, as illustrated in FIG. 7, a planarization process may be performed on the mask layer 105 in order to expose the upper surface of the semiconductor fin 107. The device isolation layer 113 may be formed on the substrate 101, e.g., on the nitride liner 111, between adjacent semiconductor fins 107. The planarization process may include, e.g., a chemical mechanical polishing (CMP) process.

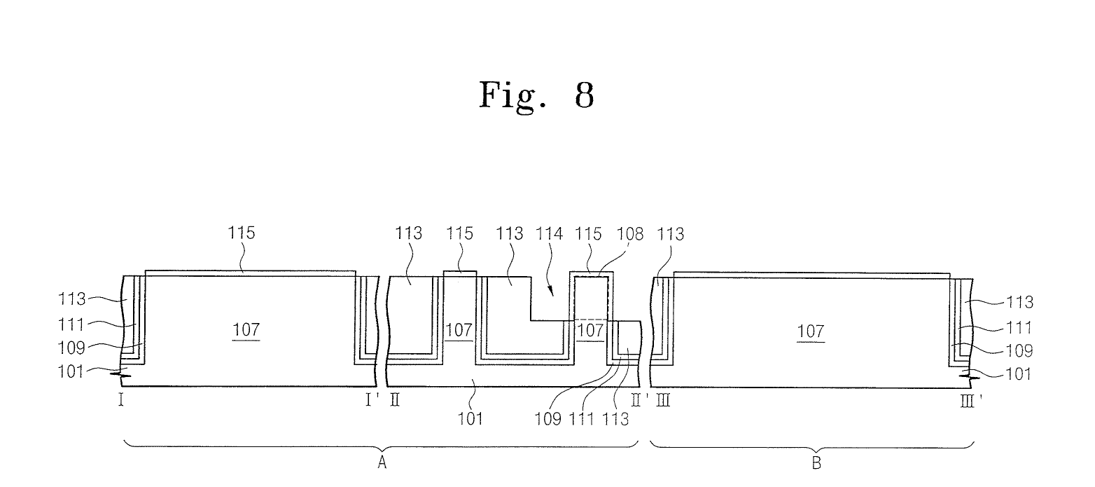

Once the planarization process is complete, the device isolation layer 113 may be selectively etched in the cell region A to form a recess region 114. More specifically, as illustrated in FIG. 8, predetermined portions of the device isolation layer 113 may be removed to expose the lateral surfaces of the semiconductor fin 107 to a predetermined depth. The recess region 114 may be sufficiently wide, i.e., as measured along the z-axis, to facilitate formation of the vertical portions 123b of the gate electrode 123 therein, i.e., portions of the first conductive layer 121. Further, the recess region 114 may be sufficiently deep, i.e., as measured along the y-axis, so the upper portion of the semiconductor fin 107, i.e., an exposed portion above the device isolation layer 113, may be defined as the channel region 108. The first oxide layer 109 and nitride liner 111 may be removed from the channel region 108 during the etch process, so the gate insulator 115 layer may be deposited, e.g., by way of a thermal oxidation process, on the surface of the semiconductor fin 107, i.e., on upper and lateral surfaces of the channel region 108.

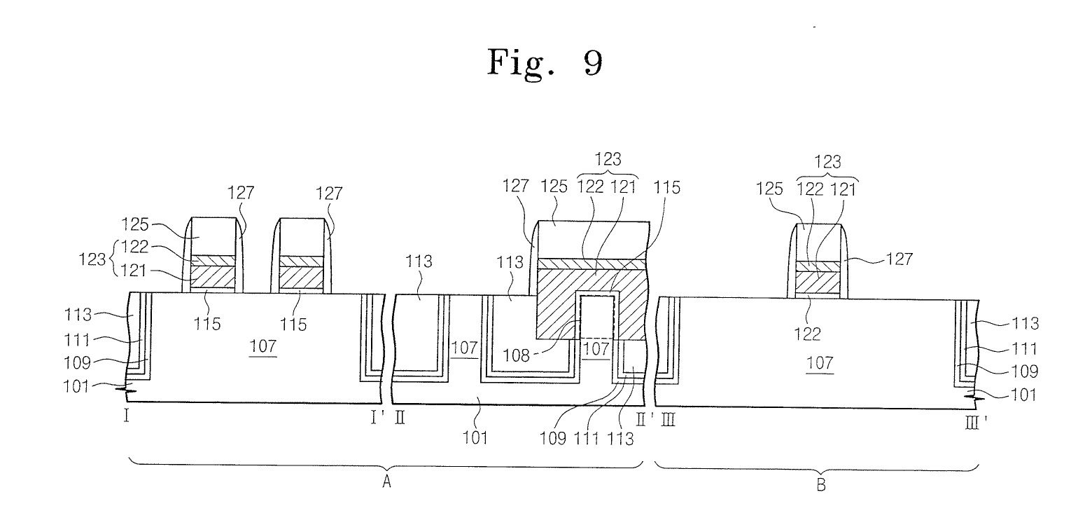

Next, as illustrated in FIG. 9, the gate electrode 123 may be formed on the substrate 101 to intersect the semiconductor fin 107. In particular, a first conductive layer (not shown), a second conductive layer (not shown), and a hard mask layer (not shown) may be sequentially formed on the entire surface of the substrate 101 and above the semiconductor fin 107, so the recess regions 114 may be filled with the first conductive layer. Subsequently, the hard mask layer, the second conductive layer, and the first conductive layer may be successively patterned to form the mask pattern 125, the second conductive pattern 122, and the first conductive pattern 121, respectively. The first conductive pattern 121 may have a π cross section, so the vertical portions thereof may be formed in the recess regions 114. The first conductive pattern 121 may be formed of, e.g., polysilicon doped with p-type impurities, and the second conductive pattern 122 may be formed of, e.g., metal and/or silicide.

The spacers 127 may be formed on the device isolation layer 113 and along each lateral surface of the gate electrode 123, i.e., along a vertically stacked structure of the first conductive pattern 121, second conductive pattern 122, and mask pattern 125, to complete formation of the gate electrode 123. Each of the spacers 127 may be formed by, e.g., depositing a silicon nitride layer on the substrate 101 and anisotropically etching the silicon nitride layer. The gate insulator 115 may be interposed between the gate electrode 123 and the semiconductor fin 107, so that the upper surface and both lateral surfaces of the semiconductor fin 107 may be in direct contact with the gate insulator 115 to facilitate functioning of the channel region 108 via three surfaces.

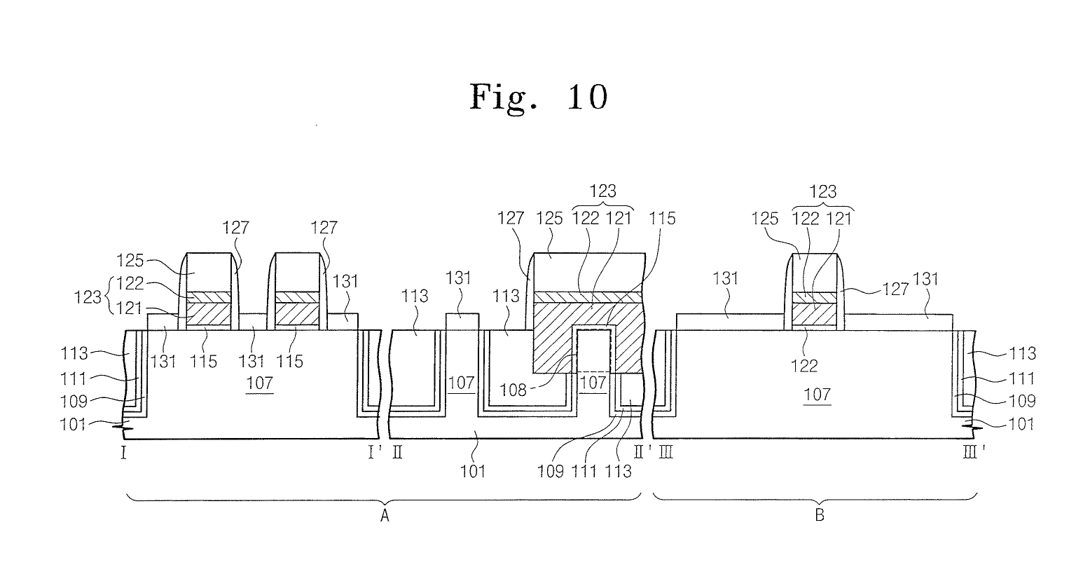

Once formation of the gate electrode 123 is complete, a lightly doped drain (LDD) region (not shown) may be formed on the semiconductor fin 107 by implanting impurity ions into the peripheral circuit region B. Next, the first epitaxial layer 131 may be grown from the semiconductor fin 107, as illustrated in FIG. 10. The first epitaxial layer 131 may be grown on each side of the gate electrode 123. A source/drain impurity region 132 may be formed in the first epitaxial layer 131 by implanting impurity ions into the first epitaxial layer 131 in the cell and peripheral circuit regions A and B. Next, a spacer (not shown) may be formed on each lateral surface of the first epitaxial layer 131 along the second direction, i.e., in parallel to a wordline direction.

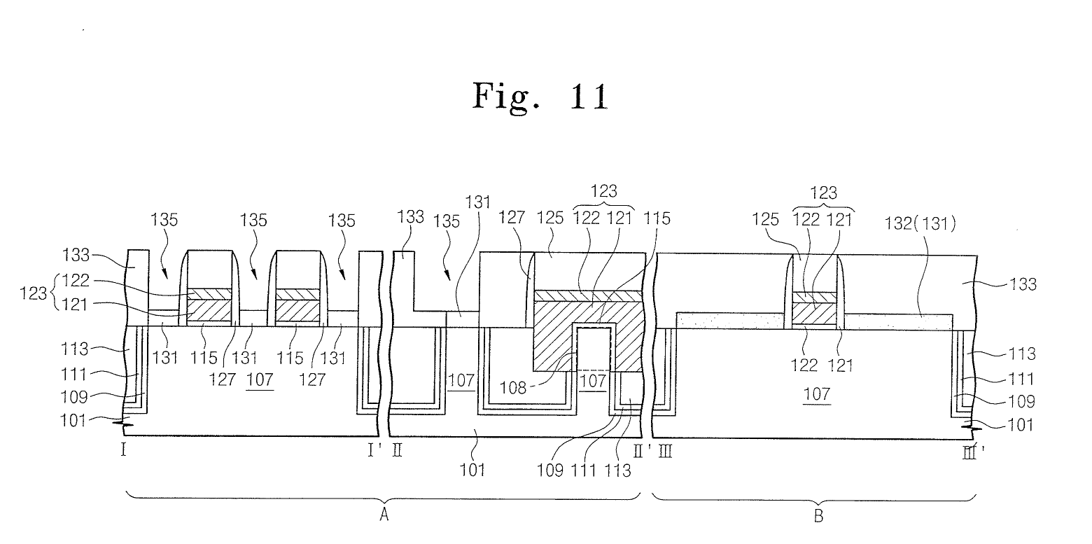

Then, an insulation layer (not shown) may be formed on the semiconductor substrate 101, followed by a planarization process to expose an upper surface of the mask pattern 125 and to form an interlayer dielectric layer 133 on the semiconductor substrate 101. The interlayer dielectric layer 133 may be patterned, as illustrated in FIG. 11, to form an opening 135 therein, so that an upper surface of the first epitaxial layer 131 in the cell region A may be exposed. The opening 135 may be wider, i.e., a distance as measured along the z-axis, than the first epitaxial layer 131.

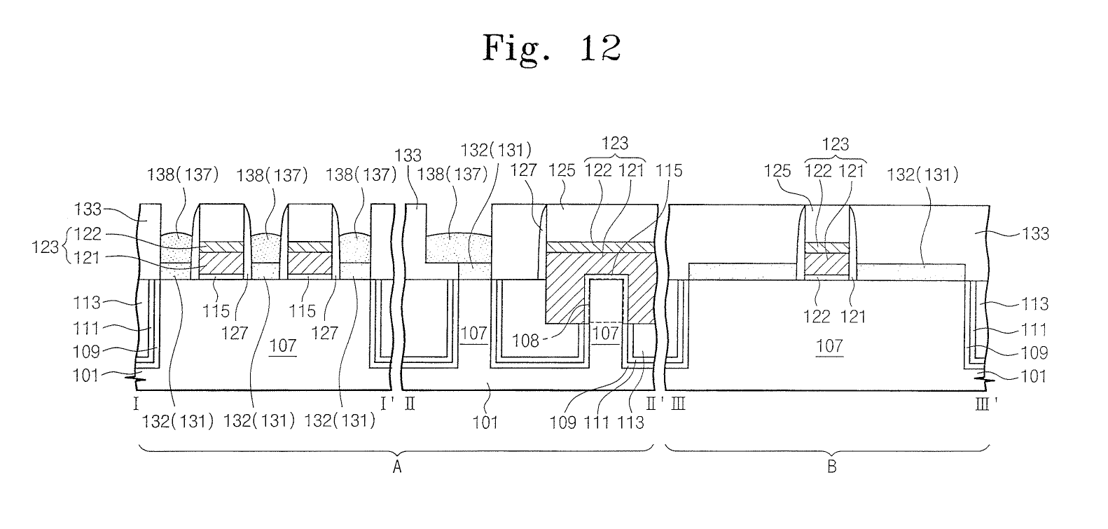

Next, as illustrated in FIG. 12, the second epitaxial layer 137 may be epitaxially grown from the first epitaxial layer 131 in the opening 135. Accordingly, the second epitaxial layer 137 may be wider, i.e., a distance as measured along the z-axis, than the first epitaxial layer 131. Further, the second epitaxial layer 137 may be thicker, i.e., a distance as measured along the y-axis, than the first epitaxial layer 131. Impurity ions may be implanted into the second epitaxial layer 137 to form contact impurity region 138 therein. The impurity ions may be implanted into the second epitaxial layer 137 after forming the second epitaxial layer 137, or may be implanted in-situ during formation of the second epitaxial layer 137. The impurity ions may be implanted at an energy level of, e.g., about 5-10 keV. The concentration of the impurity ions may decrease from the upper surface of the contact impurity region 138 to the lower surface of the source/drain impurity region 132. The concentration of the impurity ions may be about 10¹⁷-10²⁰/cm³. A hydrogen annealing process may be performed to planarize an upper surface of the contact impurity region 138, followed by formation of the contact pad 139, e.g., of doped polysilicon, thereon in the opening 135.

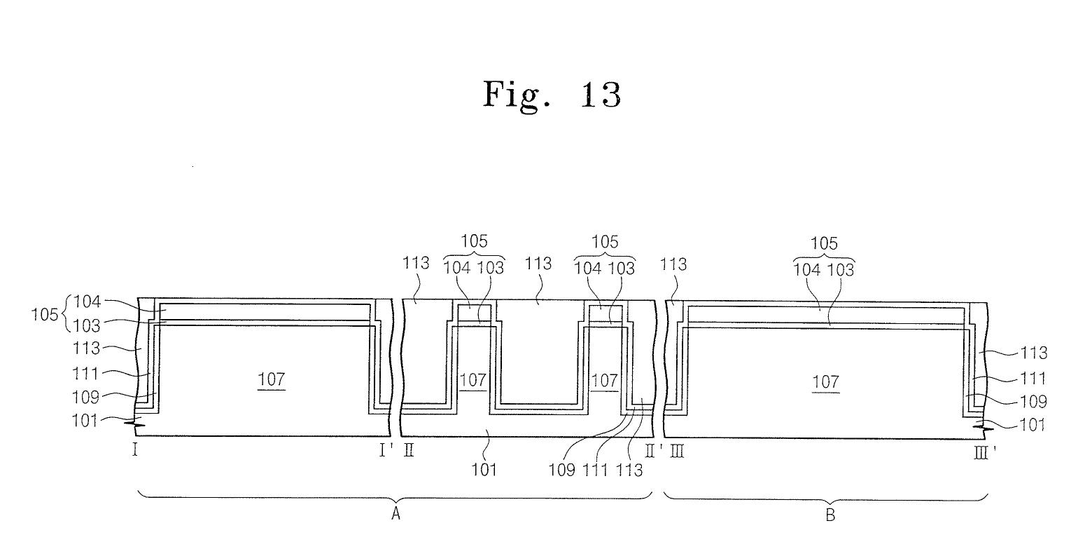

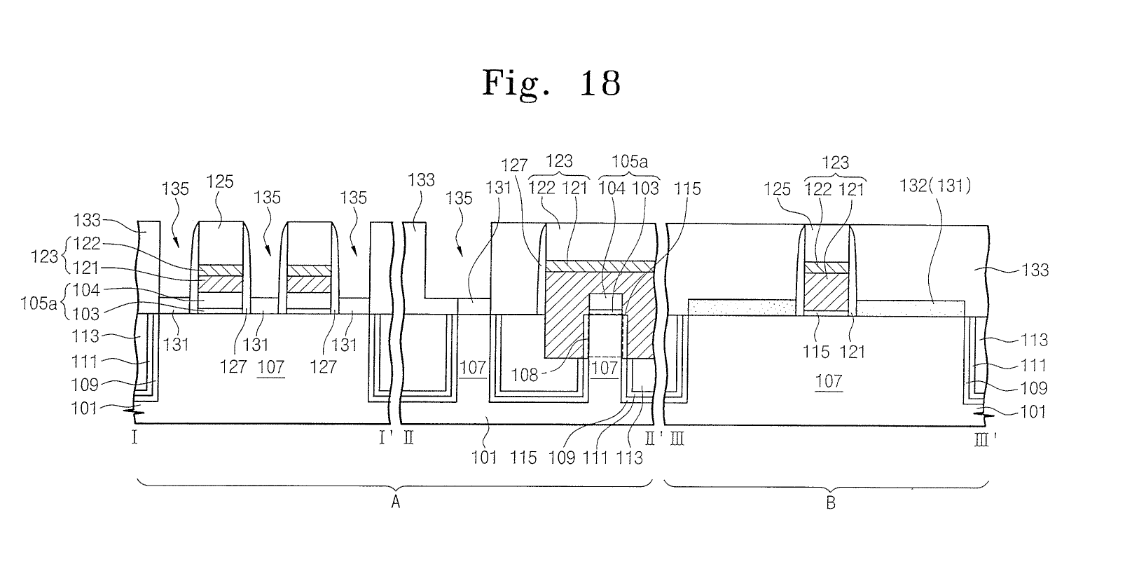

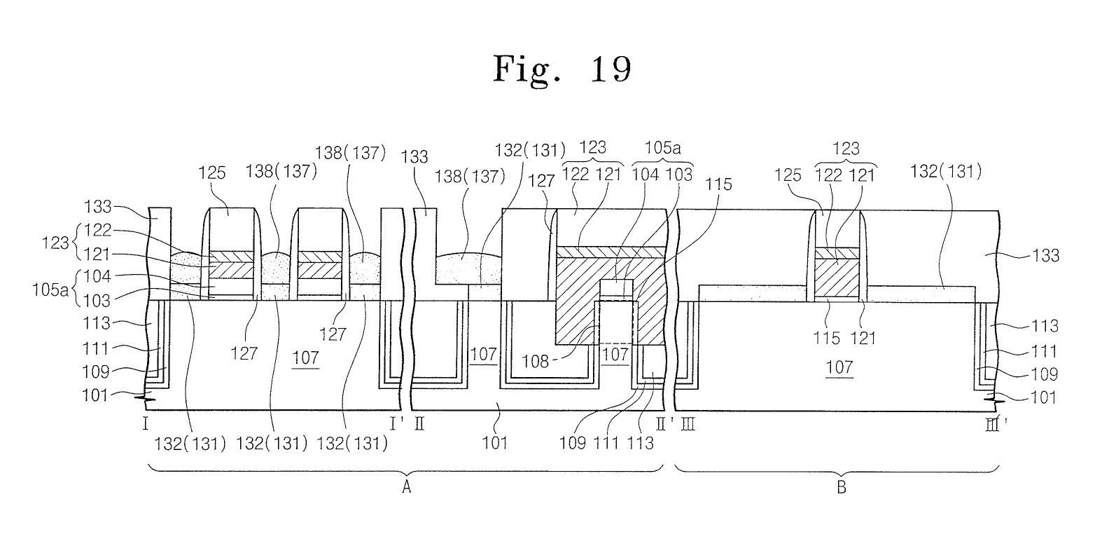

According to still another embodiment of the present invention, a method for forming the semiconductor device illustrated in FIGS. 3A-3C will be described in more detail below with respect to FIGS. 13-19. Each of FIGS. 13-19 illustrates three cross-sectional views corresponding to FIGS. 3A-3C, respectively. It is noted that deposition of the mask layer 105 to form the semiconductor fin 107, and subsequent deposition of first oxide layer 109 and nitride liner 111 are substantially identical to the processes described previously with respect to FIGS. 4-6, and therefore, will not be repeated herein.

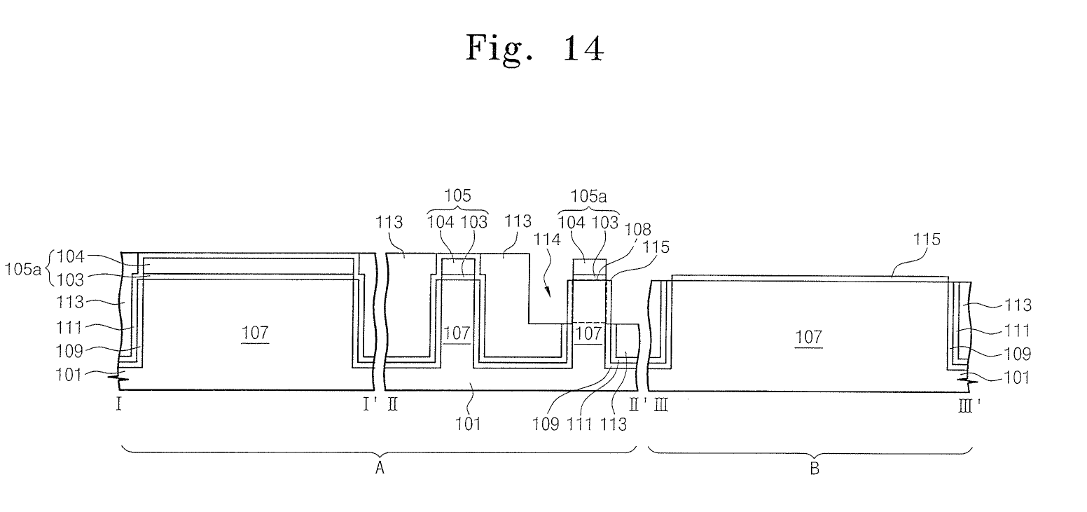

Subsequently, as illustrated in FIG. 13, an insulation layer (not shown) may be deposited on the substrate 101 to fill spaces between adjacent semiconductor fins 107. A planarization process may be performed to expose the upper surface of the nitride liner 111 of the mask layer 105 to form a device isolation layer 113 on the substrate 101 between the semiconductor fins 107. Next, as illustrated in FIG. 14, an etch process may be performed to partially etch the device isolation layer 113 in the cell region A to form the recess region 114 and to remove the mask layer 105 from the peripheral circuit region B. A portion of the mask layer 105 may remain on the upper surface of the semiconductor fin 107 to form the mask pattern 105a. Formation of the recess region 114, and removal of the first oxide layer 109 and the nitride liner 111 may be substantially similar to the process described previously with respect to FIG. 8, and therefore, will not be repeated herein. As further illustrated in FIG. 14, the gate insulator 115 may be formed on the lateral surfaces of the semiconductor fin 107 so that the upper portion of the semiconductor fin 107 may define the channel region 108.

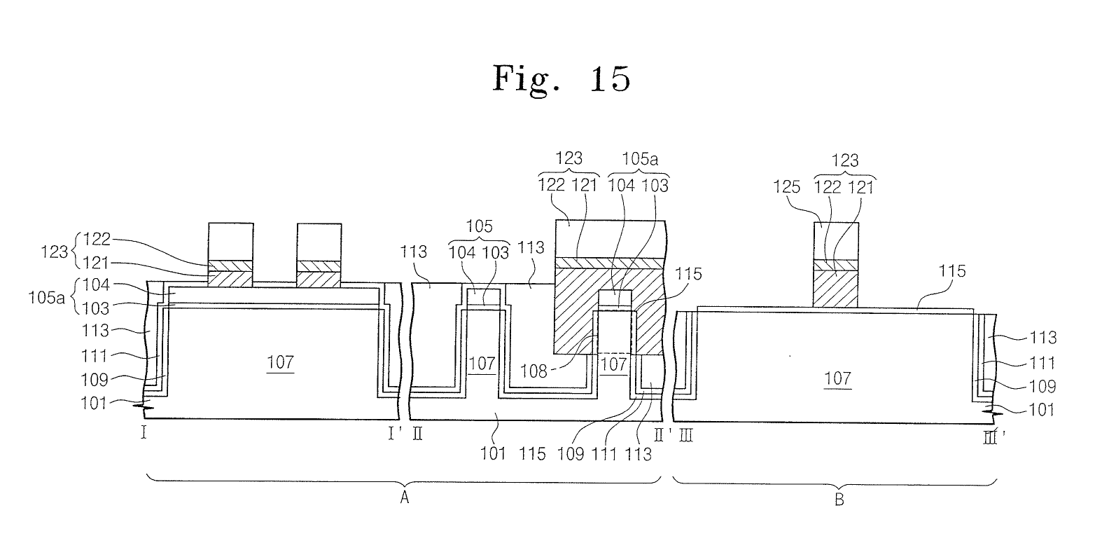

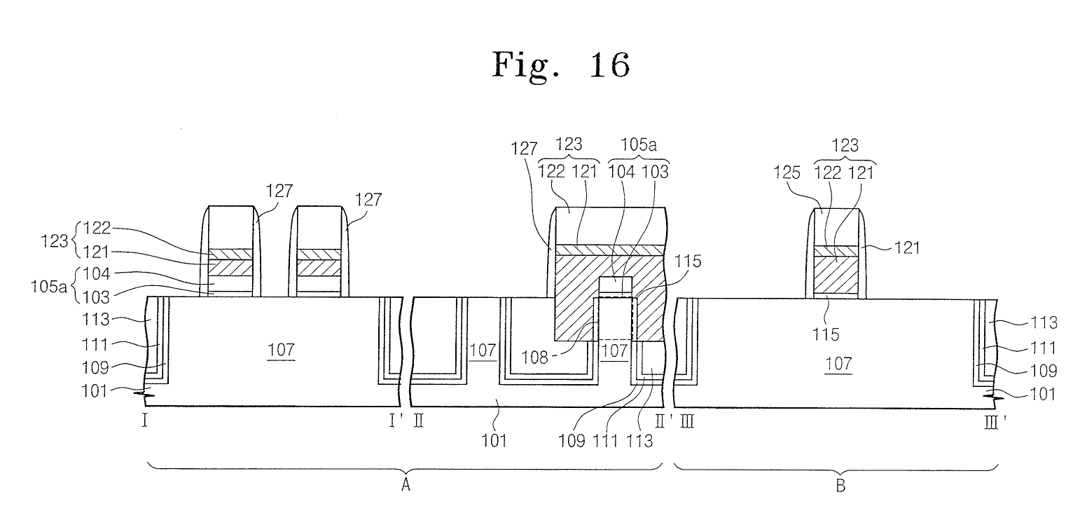

The gate electrode 123 may be formed on the substrate 101 in a process substantially similar to the process described previously with respect to FIG. 10. However, as illustrated in FIG. 15, the gate insulator 115 may be partially interposed between the gate electrode 123 and the semiconductor fin 107. More specifically, the mask pattern 105 may be interposed between the upper surface of the semiconductor fin 107 and the horizontal portion 123a of the gate electrode 123, and the gate insulator 115 may be interposed between lateral surface of the semiconductor fin 107 and the vertical portions 123b of the gate electrode 123. Accordingly, charges may move only through lateral surfaces of the channel region 108. The nitride liner 111, the mask pattern 105, and the gate insulator 115 may be removed from portions of the upper surface of the semiconductor fin 107, i.e., portions not covered by the gate electrode 123, in the cell region A and in the peripheral circuit region B to expose the upper surface of the semiconductor fin 107, as illustrated in FIG. 16.

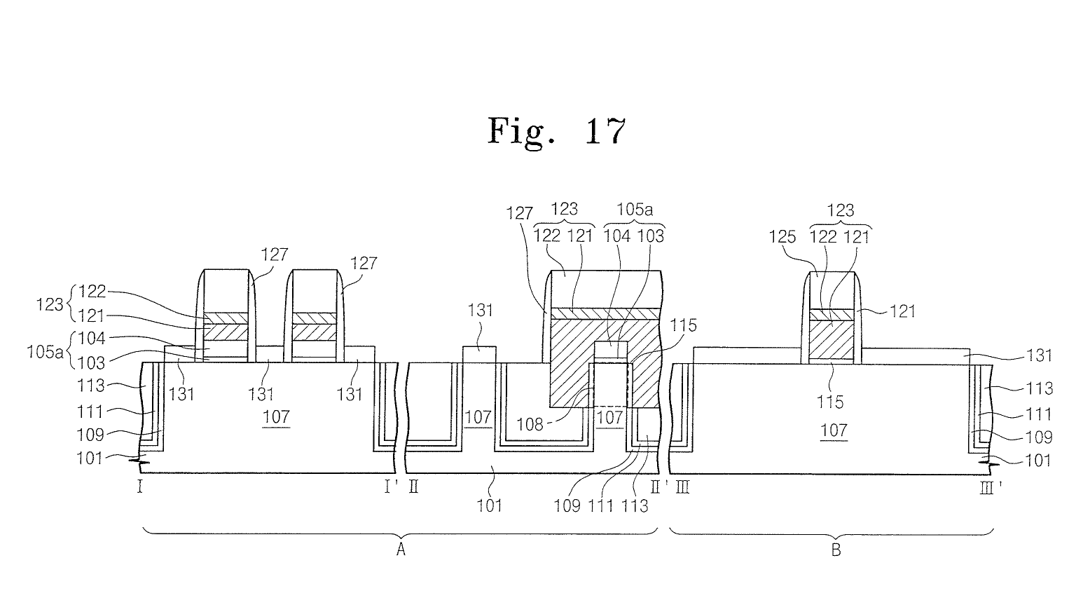

Next, as illustrated in FIGS. 17-19, the first and second epitaxial layers 131 and 132 may be grown to form the source/drain and impurity contact regions 132 and 138, respectively, followed by formation of the contact pad 139 formed according to a process substantially similar to the process described previously with respect to FIGS. 11-12.

The method of forming the semiconductor device according to embodiments of the present invention may be advantageous in minimizing GIDL, reducing the electric field formed by the gate electrode, and maintaining a high threshold voltage despite use of a p-type polysilicon gate electrode, thereby providing a highly integrated semiconductor device with improved reliability.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method for forming a semiconductor device, comprising:
forming at least one gate electrode having a bent structure along a first direction on a semiconductor substrate, the gate electrode having first and second vertical portions;
forming at least one semiconductor fin along a second direction on the semiconductor substrate, the semiconductor fin positioned between the first and second vertical portions of the gate electrode;
forming a first epitaxial layer on the semiconductor fin, the first epitaxial layer including a source/drain impurity region; and
forming a second epitaxial layer on the first epitaxial layer, the second epitaxial layer including a contact impurity region.

2. The method as claimed in claim 1, wherein forming the first and second epitaxial layers includes implanting impurity ions therein.

3. The method as claimed in claim 2, wherein implanting the impurity ions includes forming a decreasing concentration of impurity ions as a vertical distance from an upper surface of the semiconductor fin decreases.

4. The method as claimed in claim 1, wherein forming the second epitaxial layer includes an in-situ impurity ions implantation.

5. The method as claimed in claim 1, wherein forming the second epitaxial layer includes:
forming an insulation layer on the first epitaxial layer;
forming an opening in the insulation layer to expose an upper surface of the first epitaxial layer; and
performing an epitaxial process on the upper surface of the first epitaxial layer.

6. The method as claimed in claim 5, wherein forming the second epitaxial layer includes performing the epitaxial process only in a cell region of the semiconductor substrate.

7. The method as claimed in claim 5, wherein forming the second epitaxial layer includes forming the opening to be wider than the first epitaxial layer.

8. The method as claimed in claim 1, wherein forming the second epitaxial layer includes performing a hydrogen annealing process to planarize an upper surface of the second epitaxial layer.

9. The method as claimed in claim 1, wherein forming the gate electrode includes forming spacers along lateral surfaces of the gate electrode.

10. A semiconductor device, comprising:
at least one gate electrode having a bent structure along a first direction on a semiconductor substrate, the gate electrode including first and second vertical portions;
at least one semiconductor fin along a second direction on the semiconductor substrate, the semiconductor fin positioned between the first and second vertical portions of the gate electrode;
a first epitaxial layer on the semiconductor fin, the first epitaxial layer including a source/drain impurity region; and
a second epitaxial layer on the first epitaxial layer, the second epitaxial layer including a contact impurity region.

11. The semiconductor device as claimed in claim 10, wherein the gate electrode includes a cell gate electrode in a cell region of the semiconductor substrate and a peripheral circuit gate electrode in a peripheral circuit region of the semiconductor substrate.

12. The semiconductor device as claimed in claim 10, wherein the second epitaxial layer is wider than the first epitaxial layer.

13. The semiconductor device as claimed in claim 10, wherein the second epitaxial layer is thicker than the first epitaxial layer.

14. The semiconductor device as claimed in claim 10, wherein the second epitaxial layer is only in a cell region of the semiconductor substrate.

15. The semiconductor device as claimed in claim 10, wherein the second epitaxial layer has a higher average concentration of impurity ions than the first epitaxial layer.

16. The semiconductor device as claimed in claim 10, further comprising a spacer between the gate electrode and each of the first and second epitaxial layers.

17. The semiconductor device as claimed in claim 10, wherein the gate electrode encloses portions of three surfaces of the semiconductor fin to form a channel region.

18. The semiconductor device as claimed in claim 17, further comprising a mask pattern between the gate electrode and an upper surface of the semiconductor fin.

19. The semiconductor device as claimed in claim 10, wherein the gate electrode is a p-type polysilicon gate electrode.

20. The semiconductor device as claimed in claim 10, wherein the gate electrode is between two segments of the first epitaxial layer.
